(19) United States
(12) Patent Application Publication
(10) Pub. No.: US 2004/0242005 A1
(43) Pub. Date: Dec. 2, 2004

(54) Method of etching metal layers

(76) Inventors: Chentsau Ying, Cupertino, CA (US); Xiaoyi Chen, Foster City, CA (US); Padmapani C. Nallan, Hyderabad (IN); Ajay Kumar, Sunnyvale, CA (US)

Correspondence Address: Patent Counsel, Applied Materials, Inc., P.O. Box 450A, Santa Clara, CA, 95052, US

(21) Appl. No.: 10/823,989

(22) Filed: Apr. 14, 2004

Related U.S. Application Data
(60) Provisional application No. 60/462,807, filed on Apr. 14, 2003.

(51) Int. Cl. H01L 21/4763; H01L 21/302; H01L 21/461

(52) U.S. Cl. 438/691; 438/692

(57) ABSTRACT

A method of etching metal layers (e.g., niobium (Nb), titanium (Ti), tantalum (Ta), and the like) using a gas mixture comprising a chlorine-containing gas and a fluorine-containing gas is disclosed. The method provides a high etch selectivity for the metal layers over photoresist.

### CROSS-REFERENCE TO RELATED APPLICATION

This application claims benefit of U.S. Provisional Application Ser. No. 60/462,807, entitled “METHOD OF ETCHING METAL LAYERS”, filed Apr. 14, 2003, which is hereby incorporated by reference in its entirety.

### BACKGROUND OF THE INVENTION

1. Field of the Invention

The present invention generally relates to fabrication of microelectronic devices. More specifically, the present invention relates to a method for etching metal layers in a semiconductor substrate processing system.

2. Description of the Related Art

Metal layers (e.g., niobium (Nb), titanium (Ti), tantalum (Ta), and the like) are often used in the fabrication of microelectronic devices such as, for example, a resistive heater of a pen in an inkjet printer. Such metal layers are typically etched so that portions of the metal layers are removed, either partially or completely.

The metal layers are generally etched using a wet etch process or, alternatively, a physical plasma etch process, such as sputter etching, ion milling, and the like. As dimensions of the etched features (e.g., a pattern of a conductive element of the resistive heater) decrease into a sub-micron range, the wet etch processes become unable to provide accurate dimensional control of the features. The physical plasma etch processes can provide the needed dimensional control, however, these processes have low etch rates (e.g., about 5 to 100 Angstroms/min) and, as such, low productivity.

Additionally, the physical plasma etch processes may produce difficult to remove post-etch residues (e.g., metal-containing residues), as well as contaminate the process chamber with non-volatile by-products of the etch process. Removal of the residues and non-volatile compounds are time consuming routines that increase the cost of fabricating such microelectronic devices.

Therefore, there is a need in the art for an improved method of etching metal layers used in microelectronic devices.

### SUMMARY OF THE INVENTION

The present invention is a method of etching metal layers (e.g., niobium (Nb), titanium (Ti), tantalum (Ta), and the like) using a gas mixture comprising a chlorine-containing gas and a fluorine-containing gas. The method provides high etch selectivity for the metal layers over photoresist.

### BRIEF DESCRIPTION OF THE DRAWINGS

The teachings of the present invention can be readily understood by considering the following detailed description in conjunction with the accompanying drawings, in which:

FIG. 1 depicts a flow diagram of a method of etching metal layers of a film stack of a resistive heater in accordance with one embodiment of the present invention;

FIGS. 2A-2D depict a sequence of schematic, cross-sectional views of a substrate having the resistive heater film stack being formed in accordance with the method of FIG. 1;

FIG. 3 is a table summarizing exemplary illustrative embodiments of the resistive heater film stack of FIGS. 2A-2D;

FIG. 4 depicts a schematic diagram of an exemplary plasma processing apparatus of the kind used in performing portions of the inventive method; and

FIG. 5 is a table summarizing the processing parameters of one exemplary embodiment of the inventive method when practiced using the apparatus of FIG. 3.

To facilitate understanding, identical reference numerals have been used, where possible, to designate identical elements that are common to the figures.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention is a method of etching metal layers (e.g., niobium (Nb), titanium (Ti), tantalum (Ta), and the like) using a gas mixture comprising a chlorine-containing gas and a fluorine-containing gas. The method facilitates an etch process having high throughput while providing a high etch selectivity for the metal layers over photoresist.

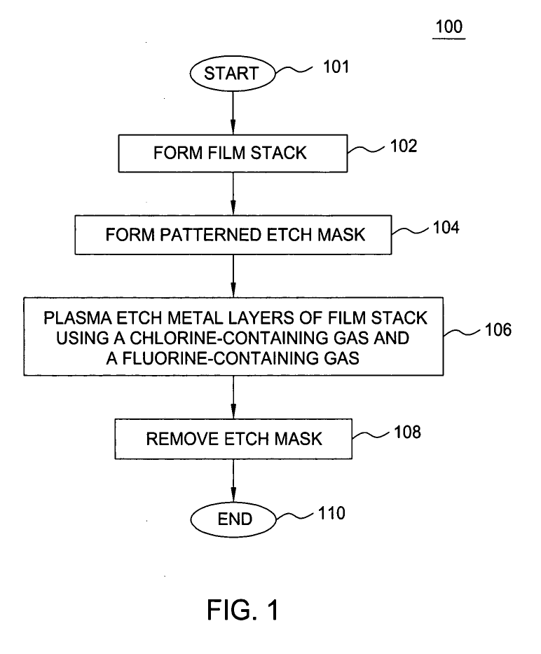

FIG. 1 depicts a flow diagram of one embodiment of the inventive method for etching a film stack of a resistive heater, as a sequence 100. The sequence 100 includes the processes that are performed upon the film stack during fabrication of the resistive heater.

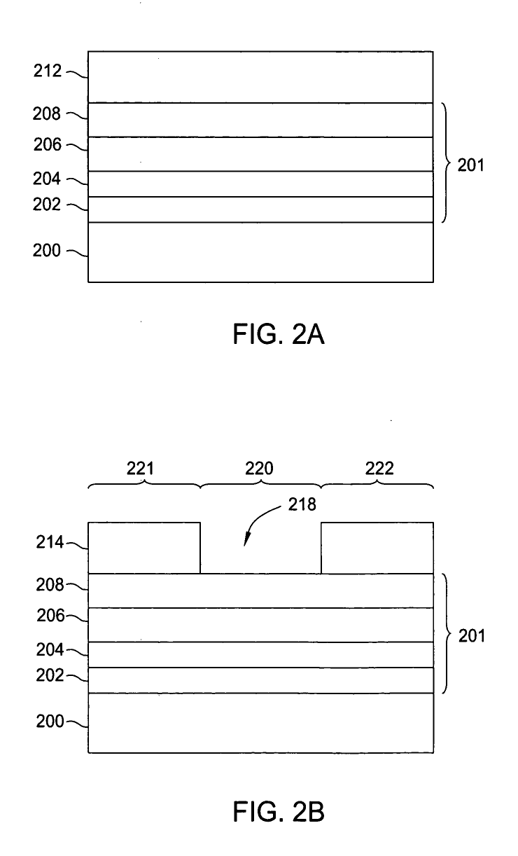

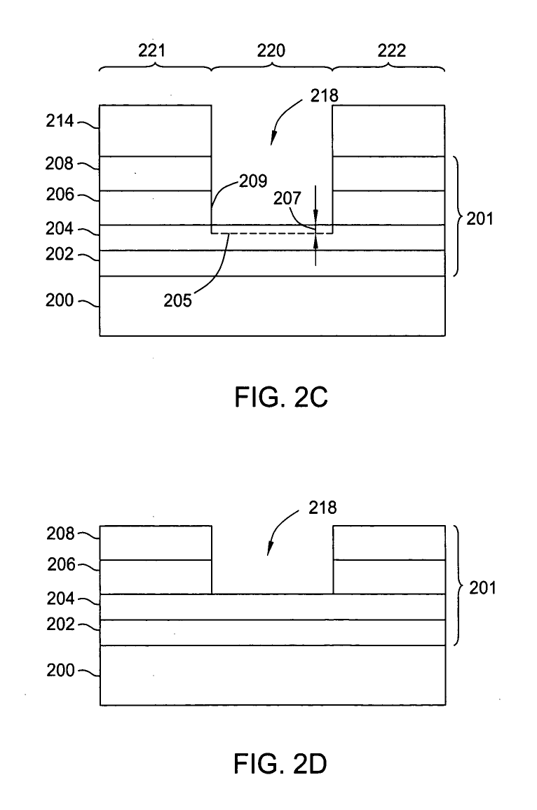

FIGS. 2A-2D depict a sequence of schematic, cross-sectional views of a substrate having a film stack of the resistive heater being fabricated using the sequence 100. The cross-sectional views in FIGS. 2A-2D relate to individual processing steps that are used for fabricating the resistive heater. To best understand the invention, the reader should simultaneously refer to FIG. 1 and FIGS. 2A-2D. Sub-processes and lithographic routines (e.g., exposure and development of photoresist, wafer cleaning procedures, and the like) are well known in the art and, as such, are not shown in FIG. 1 and FIGS. 2A-2D. The images in FIGS. 2A-2D are not depicted to scale and are simplified for illustrative purposes.

The sequence 100 starts at step 101 and proceeds to step 102, when a film stack 201 of a resistive heater is formed on a substrate 200 (FIG. 2A), such as a silicon (Si) wafer and the like. In one illustrative embodiment, the film stack 201 comprises a first dielectric layer 202, a second dielectric layer 204, a first conductive layer 206, and a second conductive layer 208. In an alternate embodiment, the film stack 201 may comprise only the dielectric layers 202, 204 and the first conductive layer 206.

In one exemplary embodiment, the first dielectric layer 202 and the second dielectric layer 204 are each formed of a dielectric material, such as silicon nitride (Si₃N₄), silicon carbide (SiC), silicon dioxide (SiO₂), hafnium dioxide (HfO₂), and the like. The first and second dielectric layers 202, 204 are generally formed to a thickness of about 1000 to 3000 Angstroms (layer 202) and about 200 to 500 Angstroms (layer 204).

The first conductive layer 206 and the second conductive layer 208 are each formed of a metal, such as niobium (Nb), titanium (Ti), tantalum (Ta), and the like. The first conductive layer 206 generally has a thickness of about 20 to 350 Angstroms. The second conductive layer 208 generally has a thickness of about 2000 to 3000 Angstroms.

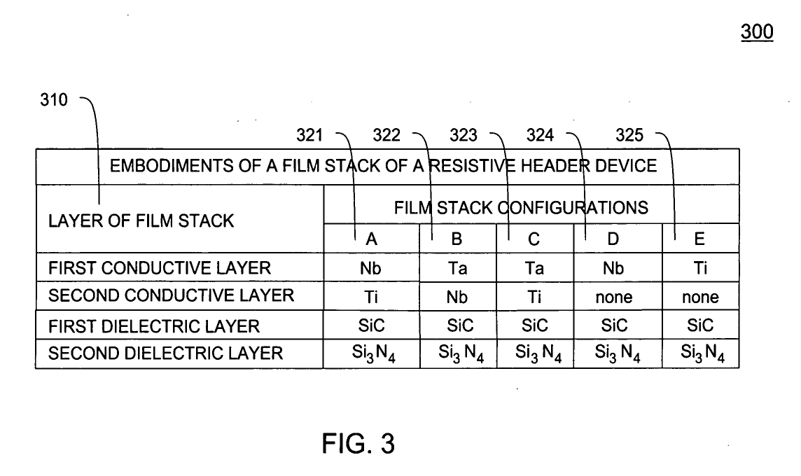

FIG. 3 is a table 300 summarizing illustrative embodiments for the film stack 201. The layers of the film stack 201 are summarized in column 310. Configurations and exemplary materials comprising the respective layers (column 310) of the film stack 201 are presented in columns 321-325. Configurations “A”, “B”, and “C” depicted in columns 321-323 illustrate the film stack 201 as including two metal layers (layer 206 and layer 208). Similarly, configurations “D” and “E” “depicted in columns 324-325 illustrate the film stack 201 having only one conductive layer (layer 206). It should be understood that, in other embodiments, the film stack 201 may comprise layers that are formed from different materials.

The layers of the film stack 201 can be formed using any conventional thin film deposition technique, such as atomic layer deposition (ALD), physical vapor deposition (PVD), chemical vapor deposition (CVD), plasma enhanced CVD (PECVD), and the like. Fabrication of the resistive heater film may be performed using the respective processing reactors of CENTURA®, ENDURA®, and other semiconductor wafer processing systems available from Applied Materials, Inc. of Santa Clara, Calif.

At step 104, a mask layer 212 is formed on the second conductive layer 208 of the film stack 201. The mask layer 212 is generally a photoresist layer formed using conventional photoresist application techniques. Additionally, the mask layer 212 may comprise an anti-reflective layer (not shown) that controls the reflection of light used to expose the photoresist. As feature sizes are reduced, inaccuracies in an etch mask pattern transfer process can arise from optical limitations that are inherent to the lithographic process, such as light reflection. The anti-reflective layer may comprise, for example, silicon nitride (Si₃N₄), polyamides, and the like. Alternatively, the mask layer 212 may be formed of Advanced Patterning Film™ (APF) (available from Applied Materials, Inc. of Santa Clara, Calif.), silicon dioxide (SiO₂), hafnium dioxide (HfO₂), and the like.

The mask layer 212 is patterned to form a patterned mask 214 (FIG. 2B). The patterned mask 214 defines the location and topographic dimensions of a trench 218 to be etched in the film stack 201. Specifically, the patterned mask 214 protects regions 221, 222 and exposes region 220 of the substrate 200. The patterned mask 214 may be formed using a lithographic patterning process. During such a patterning process, the mask layer 212 is exposed through a patterned reticle, developed, and then the undeveloped portion of the mask layer is removed. The remaining developed mask layer is generally a polymer that defines the patterned mask 214.

Processes of forming the patterned mask 214 are described, for example, in commonly assigned U.S. patent application Ser. No. 10/218,244, filed Aug. 12, 2002, Ser. No. 09/590,322, filed Jun. 8, 2000, and Ser. No. 10/245,130, filed Sep. 16, 2002, which are incorporated herein by reference.

At step 106, the second conductive layer 208 and the first conductive layer 206 are etched and removed in the unprotected region 220 (FIG. 2C). In one embodiment, step 106 uses a gas mixture comprising a chlorine-containing gas and a fluorine-containing gas. The chlorine-containing gas may comprise chlorine (Cl₂), boron trichloride (BCl₃), carbon tetrachloride (CCl₄), silicon tetrachloride (SiCl₄), hydrogen chloride (HCl), and the like. The fluorine-containing gas may comprise carbon tetrafluoride (CF₄), trifluoromethane (CHF₃), nitrogen fluoride (NF₃), and the like.

In the depicted embodiment, step 106 forms the trench 218. Step 106 uses the patterned mask 214 as an etch mask and may use the second dielectric layer 204 as an etch stop layer. Alternatively, step 106 may continue until a recess 205 (shown in broken line) having a pre-determined depth 207 is formed in the second dielectric layer 204. To determine the endpoint of the etch process, the etch reactor may use an endpoint detection system to monitor plasma emissions at a particular wavelength, control of process time, laser interferometery, and the like.

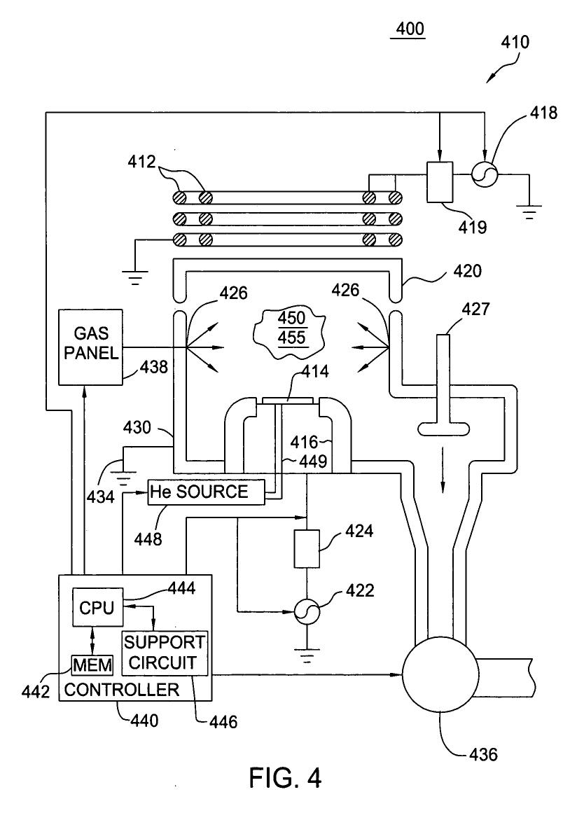

Step 106 can be performed using an etch reactor such as a Decoupled Plasma Source (DPS) II module of the CENTURA® system. The DPS II module (described in detail with reference to FIG. 4 below) uses an inductive source (i.e., antenna) to produce a high-density plasma.

In one illustrative embodiment, the second conductive layer 208 and the first conductive layer 206 comprising a film of one of niobium (Nb), titanium (Ti), and tantalum (Ta), as described above in reference to Table 300, are etched in the DPS II module by providing a chlorine-containing gas, e.g., chlorine (Cl₂), at a rate of 10 to 300 sccm and a fluorine-containing gas, e.g., carbon tetrafluoride (CF₄), at a rate of 10 to 300 sccm (i.e., a Cl₂:CF₄ flow ratio ranging from 1:30 to 30:1), applying power to an inductively coupled antenna of about 200 to 3000 W, applying a cathode bias power of about 0 to 500 W, and maintaining a wafer temperature between 10 and 350 degrees Celsius at a pressure in the process chamber between 2 and 50 mTorr. One illustrative etch process provides Cl₂ at a rate of 100 sccm, CF₄ at a rate of 20 sccm (i.e., a Cl₂:CF₄ flow ratio of about 5:1), applies 300 W of power to the antenna, 50 W of bias power, and maintains a wafer temperature of 40 degrees Celsius at a pressure of 5 mTorr.

Such etch processes provide an etch rate of about 1000 Angstroms/min and etch selectivity for Nb/Ti/Ta (layers 206 and 208) over silicon carbide (layer 204) of at least 1:1, as well as etch selectivity for Nb/Ti/Ta over the photoresist (mask 214) of about 1:1. The process may be tuned to minimize the post-etch residues and non-volatile by-products and to form the trench 218 having substantially vertical and smooth sidewalls 209.

At step 108, the patterned mask 214 is optionally removed (or stripped) (FIG. 2D). Simultaneously with stripping the patterned mask 214, traces of non-volatile by-products and post-etch residue, when present, may be removed from the film stack 201 and elsewhere on the substrate 200. In one illustrative embodiment, the patterned mask 214 is stripped using a plasma comprising oxygen (O₂). Such a photoresist stripping process may be performed, e.g., using the Advanced Strip and Passivation (ASP) module or the AXIOM® reactor of the CENTURA® system. One photoresist stripping process is disclosed in U.S. patent application Ser. No. 10/245,130, filed Sep. 16, 2002.

The ASP module is a microwave downstream plasma reactor in which a plasma is confined such that only reactive neutrals are allowed to enter the process chamber thereby precluding plasma-related damage to the substrate or integrated circuits formed on the substrate. The AXIOM® reactor is a remote plasma reactor. The AXIOM® reactor is described in detail in U.S. patent application Ser. No. 10/264,664, filed Oct. 4, 2002, which is herein incorporated by reference.

Alternatively, step 108 may be performed using the DPS II module by providing oxygen (O₂) at a rate of 10 to 100 sccm, nitrogen (N₂) at a rate of 10 to 100 sccm (i.e., a O₂: N₂ flow ratio ranging from 1:10 to 10:1), applying power to inductively coupled antenna of about 1000 W, applying a cathode bias power of about 10 W, and maintaining a wafer temperature of about 40 degrees Celsius at a pressure in the process chamber of about 32 mTorr. For such an embodiment, the duration of the stripping process is generally between 30 and 120 seconds.

At step 110, the sequence 100 ends.

Inkjet printing devices typically include a plurality of resistive heaters positioned along an ink path (trench 218) that is adjacent to a discharge opening of the inkjet device. When current is momentarily applied to heat the plurality of resistive heaters, ink in the liquid path is heated and bubbles form causing a volume change along the ink path, thereby forcing ink out of the ink path through the discharge opening.

FIG. 4 depicts a schematic diagram of the exemplary Decoupled Plasma Source (DPS) II etch reactor 400 that illustratively may be used to practice portions of the invention. The DPS II reactor is available from Applied Materials, Inc. of Santa Clara, Calif.

The reactor 400 comprises a process chamber 410 having a wafer support pedestal 416 within a conductive body (wall) 430, and a controller 440.

The chamber 410 is supplied with a substantially flat dielectric ceiling 420 (e.g., DPS II module). Other modifications of the chamber 410 may have other types of ceilings such as, for example, a dome-shaped ceiling (e.g., DPS Plus module). Above the ceiling 420 is disposed an antenna comprising at least one inductive coil element 412 (two co-axial elements 412 are shown). The inductive coil element 412 is coupled, through a first matching network 419, to a plasma power source 418. The plasma source 418 typically is capable of producing up to 4000 W at a tunable frequency in a range from 50 kHz to 13.56 MHz.

The support pedestal (cathode) 416 is coupled, through a second matching network 424, to a biasing power source 422. The biasing power source 422 generally is a source of up to 500 W at a frequency of approximately 13.56 MHz that is capable of producing either continuous or pulsed power. In other embodiments, the biasing power source 422 may be a DC or pulsed DC source.

A controller 440 comprises a central processing unit (CPU) 444, a memory 442, and support circuits 446 for the CPU 444 and facilitates control of the components of the DPS II etch process chamber 410 and, as such, of the etch process, as discussed below in further detail.

In operation, a semiconductor wafer 414 is placed on the pedestal 416 and process gases are supplied from a gas panel 438 through entry ports 426 to form a gaseous mixture 450. The gaseous mixture 450 is ignited into a plasma 455 in the chamber 410 by applying power from the plasma and bias sources 418 and 422 to the inductive coil element 412 and the cathode 416, respectively. The pressure within the interior of the chamber 410 is controlled using a throttle valve 427 and a vacuum pump 436. Typically, the chamber wall 430 is coupled to an electrical ground 434. The temperature of the wall 430 is controlled using liquid-containing conduits (not shown) that run through the wall 430.

The temperature of the wafer 414 is controlled by stabilizing a temperature of the support pedestal 416. In one embodiment, helium gas from a gas source 448 is provided via a gas conduit 449 to channels (not shown) formed in the pedestal surface under the wafer 414. The helium gas is used to facilitate heat transfer between the pedestal 416 and the wafer 414. During wafer processing, the pedestal 416 may be heated by a resistive heater (not shown) within the pedestal to a steady state temperature and then the helium gas facilitates uniform heating of the wafer 414. Using such thermal control, the wafer 414 is maintained at a temperature of between 0 and 500 degrees Celsius.

Those skilled in the art will understand that other forms of etch chambers may be used to practice the invention, including chambers with remote plasma sources, electron cyclotron resonance (ECR) plasma chambers, and the like.

To facilitate control of the process chamber 410 as described above, the controller 440 may be one of any form of general-purpose computer processor that can be used in an industrial setting for controlling various chambers and sub-processors. The memory, or computer-readable medium 442, of the CPU 444, may be one or more of readily available memory such as random access memory (RAM), read only memory (ROM), floppy disk, hard disk, or any other form of digital storage, local or remote. The support circuits 446 are coupled to the CPU 444 for supporting the processor in a conventional manner. These circuits include cache, power supplies, clock circuits, input/output circuitry and subsystems, and the like. The inventive method is generally stored in the memory 442 as a software routine. The software routine may also be stored and/or executed by a second CPU (not shown) that is remotely located from the hardware being controlled by the CPU 444.

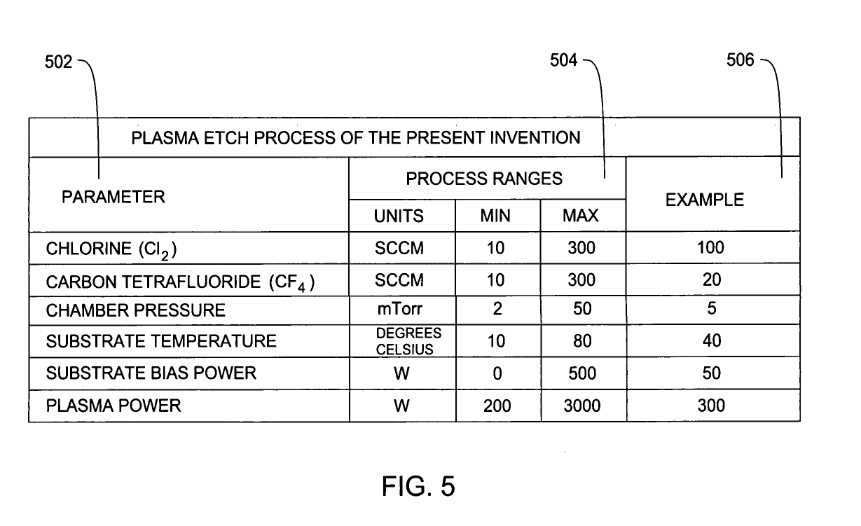

FIG. 5 is a table 500 summarizing the process parameters of the etch process described herein using the DPS 11 reactor. The process parameters summarized in column 502 are for one exemplary embodiment of the invention presented above. The process ranges are presented in column 504. Exemplary process parameters for etching the second conductive layer 208 and the first conductive layer 206 are presented in column 506. It should be understood, however, that the use of a different plasma etch reactor may necessitate different process parameter values and ranges.

The invention may be practiced using other semiconductor wafer processing systems wherein the processing parameters may be adjusted to achieve acceptable characteristics by those skilled in the art by utilizing the teachings disclosed herein without departing from the spirit of the invention.

Although the forgoing discussion referred to fabrication of the resistive heater, fabrication of the other devices and structures that are used in microelectronic devices can benefit from the invention.

While the foregoing is directed to the illustrative embodiment of the present invention, other and further embodiments of the invention may be devised without departing from the basic scope thereof, and the scope thereof is determined by the claims that follow.

What is claimed is:

1. A method of etching, comprising:
providing a substrate having a patterned mask over at least one metal layer in a processing chamber; and
exposing the metal layer to a gas mixture through the mask, the gas mixture comprising a chlorine-containing gas and a fluorine-containing gas.

2. The method of claim 1, wherein the at least one metal layer comprises at least a first metal layer selected from the group consisting of niobium, titanium and tantalum.

3. The method of claim 2, wherein the at least one metal layer further comprises a second metal layer selected from the group consisting of niobium, titanium and tantalum.

4. The method of claim 1, wherein the step of exposing further comprises:
flowing at least one of Cl₂, BCl₃, CCl₄, SiCl₄ and HCl into the processing chamber.

5. The method of claim 1, wherein the step of exposing further comprises:
flowing at least one of CF₄, CHF₄ and NF₄ into the processing chamber.

6. The method of claim 1, wherein the mask comprises a photoresist layer.

7. The method of claim 6, wherein the mask further comprises an anti-reflective layer disposed between the photoresist layer and the at least one metal layer.

8. The method of claim 7, wherein the anti-reflective layer further comprises at least one of Si₃N₄ and polyamide.

9. The method of claim 1 further comprising:
forming a plasma from the gas mixture.

10. The method of claim 1 further comprising:
removing the mask.

11. The method of claim 10, wherein the step of removing the mask further comprise:
exposing the mask to a plasma comprising oxygen.

12. A method of etching, comprising:
providing a substrate having a first metal layer, a second metal layer disposed on the first metal layer, and a patterned mask disposed over the second metal layer; and
exposing the second metal layer through the mask to a gas mixture in a processing chamber; the gas mixture comprising a chlorine-containing gas and a fluorine-containing gas.

13. The method of claim 12, wherein the first metal layer comprises niobium and the second metal layer comprises titanium.

14. The method of claim 12, wherein the first metal layer comprises tantalum and the second metal layer comprises niobium.

15. The method of claim 12, wherein the first metal layer comprises tantalum and the second metal layer comprises titanium.

16. The method of claim 12, wherein the substrate further comprises a layer of Si₃N₄ disposed under the first metal layer and a layer of SiC disposed under the layer of Si₃N₄.

17. The method of claim 12, wherein the step of exposing further comprises:
flowing at least one of Cl₂, BCl₃, CCl₄, SiCl₄ and HCl into the processing chamber.

18. The method of claim 17, wherein the step of exposing further comprises:
flowing at least one of CF₄, CHF₄ and NF₄ into the processing chamber.

19. The method of claim 12, wherein the step of exposing further comprises:
flowing Cl₂ and CF₄ into the processing chamber.

20. The method of claim 19, wherein the step of exposing further comprises:
forming a plasma from the gas mixture.

21. The method of claim 20, wherein the step of forming the plasma further comprises:
inductively coupling about 200 to 3000 Watts of power to the gas mixture.

22. The method of claim 21 further comprising:
applying about 0 to 500 Watts of bias power;
maintaining the substrate at about 10 to 350 degrees Celsius; and
maintaining a chamber pressure of about 2 to 50 mTorr.

23. The method of claim 12, wherein the mask comprises:
a photoresist layer disposed on the second metal layer; and
a silicon carbide layer underlying the first metal layer.

24. The method of claim 23, wherein the etch selectivity of the first metal layer to photoresist is at least 1:1; and
wherein the etch selectivity of the first metal layer to silicon carbide at least 1:1.

25. The method of claim 1 further comprising:
removing the mask.

26. The method of claim 25, wherein the step of removing the mask further comprise:
exposing the mask to a plasma comprising oxygen.

27. The method of claim 26, wherein the step of exposing and removing are performed without removing the substrate from the processing chamber.

28. The method of claim 12, wherein the substrate further comprises a dielectric layer disposed under the first metal layer, the dielectric layer comprising at least one of Si₃N₄, SiC and HfO₂.

29. The method of claim 12, wherein the step of exposing further comprises:
forming a trench through the first and second metal layers.

30. The method of claim 30, wherein the step of forming the trench further comprises:
extending the trench into a dielectric layer disposed below the first metal layer.
